(19) United States
(12) Patent Application Publication
(10) Pub. No.: US 2007/0267669 A1
(43) Pub. Date: Nov. 22, 2007

(54) Phase-changeable memory device and method of manufacturing the same

(76) Inventors: Hyeong-Jun Kim, Seoul (KR); Byung-Seo Kim, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/783,531

(22) Filed: Apr. 10, 2007

(30) Foreign Application Priority Data
May 19, 2006 (KR) 2006-45091

(51) Int. Cl. H01L 29/94

(52) U.S. Cl. 257/296

(57) ABSTRACT

A phase-changeable memory device may include a substrate including a peripheral region and a cell region, a first pad on the peripheral region, a second pad on the cell region, a lower electrode on the second pad, an insulation layer pattern on the substrate, the insulation layer pattern including a first opening exposing the lower electrode and a second opening exposing the first pad, a phase-changeable layer pattern including a phase-changeable material and being in the first opening, a metal plug in the second opening, the metal plug having an upper surface higher than that of an upper surface of the phase-changeable layer pattern, an upper electrode formed on the phase-changeable layer pattern, and a conductive wiring formed on the metal plug.

### BACKGROUND OF THE INVENTION

1. Field of the Invention

One or more aspects of the present invention relate to a phase-changeable memory device and a method of manufacturing the same. More particularly, one or more aspects of the invention relate to a phase-changeable memory device including a phase-changeable material and a method of manufacturing such a phase-changeable memory device.

2. Description of the Related Art

Examples of memory devices include a dynamic random access memory (DRAM) device, a static random access memory (SRAM) device, a flash memory device, etc. Memory devices may be classified as either a volatile memory device or a non-volatile memory device depending on whether the memory device stores or removes data when a current is not provided to the memory device. Non-volatile memory devices, e.g., flash memory devices, which are capable of storing data when current is not provided, have been widely used as a data-storing memory device in, e.g., MP3 players, cellular phones, etc. However, flash memory devices generally take more time to read/write data. Thus, a ferro-electric RAM, a magnetic RAM, a phase-changeable RAM (PRAM), etc., have been proposed as next generation memory devices.

The PRAM may write and read data using a phase-changeable material that has a crystalline structure of phases to be changed into an amorphous structure or contrariwise by heat. The PRAM device may include a lower electrode, a phase-changeable layer pattern and an upper electrode. The phase-changeable layer pattern may be interposed between the lower electrode and the upper electrode. Examples of the phase-changeable material include chalcogenides having germanium (Ge), stibium (Sb) and tellurium (Te).

More particularly, in the PRAM, a current may flow through the phase-changeable layer pattern and may heat the phase-changeable layer pattern. That is, when the current flows through the phase-changeable layer pattern by a voltage difference between the lower electrode and the upper electrode, a phase of the phase-changeable layer pattern may be changed into an amorphous structure from a single crystalline structure, which may have a resistance lower than that of the amorphous structure. In contrast, when the current provided to the phase-changeable layer pattern is lower than a predetermined current or the current is not provided to the phase-changeable layer pattern, the phase of the phase-changeable layer pattern may be changed into the single crystalline structure from the amorphous structure. Thus, the PRAM including the phase-changeable layer pattern, the lower electrode and the upper electrode may have a variable resistance due to the phase change of the phase-changeable layer pattern.

According to a conventional method of forming a PRAM, a phase-changeable layer is formed on a lower electrode. A metal nitride layer is formed on the phase-changeable layer. The metal nitride layer and the phase-changeable layer are etched to form an upper electrode and a phase-changeable layer pattern.

However, when the upper electrode and the phase-changeable layer pattern are simultaneously formed by the etching process using an etchant, the etchant may react with the phase-changeable layer so that electrical characteristics of the phase-changeable layer may be deteriorated. Further, as a cell size of the PRAM is reduced, the above-mentioned problem may become a serious matter.

### SUMMARY OF THE INVENTION

The invention is therefore directed to phase-changeable memory devices and methods of manufacturing a phase-changeable memory device, which substantially overcome one or more of the problems due to the limitations and disadvantages of the related art.

It is therefore a feature of an embodiment of the present invention to provide a phase-changeable memory device and a method of manufacturing such a phase-changeable memory device having a structure that protects the electrical and/or physical characteristics of a phase-changeable layer from being deteriorated during processing.

At least one of the above and other features and advantages of the present invention may be realized by providing a phase-changeable memory device, including a substrate including a peripheral region and a cell region, a first pad on the peripheral region, a second pad on the cell region, a lower electrode on the second pad, an insulation layer pattern on the substrate, the insulation layer pattern including a first opening exposing the lower electrode and a second opening exposing the first pad, a phase-changeable layer pattern including a phase-changeable material and being in the first opening, a metal plug in the second opening, the metal plug having an upper surface higher than that of an upper surface of the phase-changeable layer pattern, an upper electrode formed on the phase-changeable layer pattern, and a conductive wiring formed on the metal plug.

The first and second pads may have upper surfaces extending along substantially a same plane. The phase-changeable memory device may include a switching element electrically connected to the lower electrode. The lower electrode and the phase-changeable layer pattern have a one-to-one correspondence with each other. The metal plug may protrude upward from an upper surface of the insulation layer pattern.

The insulation layer pattern may be a multi-layer structure. An upper surface of the phase-changeable layer pattern may extend on substantially a same plane as a plane along which an upper surface of the insulation layer pattern extends.

The conductive wiring may contact a portion of the upper surface of the insulation layer pattern that extends along substantially the same plane as the plane along which the upper surface of the phase-changeable layer pattern extends.

The conductive wiring may contact an upper surface and at least one side surface of an upper portion of the metal plug. The conductive wiring may have a stepped structure having a substantially uniform thickness.

At least one of the above and other features and advantages of the present invention may be separately realized by providing a method of manufacturing a phase-changeable memory device, including forming an insulation layer on a substrate including a peripheral region on which a first pad is formed and a cell region on which a second pad and a lower electrode are sequentially formed, patterning the insulation layer to form a preliminary insulation layer pattern having a first opening exposing the lower electrode, filling the first opening with a phase-changeable layer pattern, patterning the preliminary insulation layer pattern on the peripheral region to form an insulation layer pattern having a second opening exposing the first pad, filling the second opening with a metal plug that has a protruded portion that protrudes from the insulation layer pattern, and forming conductive wiring and an upper electrode on the insulation layer pattern, the conductive wiring being electrically connected to the metal plug and the upper electrode being electrically connected to the phase-changeable layer pattern.

Forming the insulation layer pattern may include forming a capping layer pattern on the preliminary insulation layer pattern, the capping layer pattern partially exposing the preliminary insulation layer pattern in the peripheral region, and etching the preliminary insulation layer pattern using the capping layer pattern as an etching mask to form the insulation layer pattern.

The capping layer pattern may include an oxide/silicon nitride layer or a metal/silicon nitride layer. Forming the metal plug may include forming a metal layer on the capping layer pattern to fill up the second opening, partially removing the metal layer to expose an upper surface of the capping layer pattern, and removing the capping layer pattern.

The conductive wiring and the upper electrode may be simultaneously formed. Forming the conductive wiring and the upper electrode may include forming a conductive layer having a uniform thickness on the phase-changeable layer pattern and the metal plug, and patterning the conductive layer to form the conductive wiring on the metal plug and the upper electrode on the phase-changeable layer pattern.

The conductive layer may include tungsten, titanium, titanium nitride, tantalum, tantalum nitride, molybdenum nitride, niobium nitride, titanium-silicon nitride, aluminum, titanium-aluminum nitride, titanium-boron nitride, zirconium-silicon nitride, tungsten-silicon nitride, tungsten-boron nitride, zirconium-aluminum nitride, molybdenum-silicon nitride, molybdenum-aluminum nitride, tantalum-silicon nitride, tantalum-aluminum nitride or a combination thereof.

The phase-changeable layer pattern may include germanium-antimony-tellurium (Ge—Sb—Te), arsenic-antimony-tellurium (As—Sb—Te), tin-antimony-tellurium (Sn—Sb—Te), tin-indium-antimony-tellurium (Sn—In—Sb—Te), arsenic-germanium-antimony-tellurium (As—Ge—Sb—Te) or indium-antimony-tellurium-silver (In—Sb—Te—Ag).

Forming the phase-changeable layer pattern may include forming a phase-changeable layer on the preliminary insulation layer pattern to fill up the first opening, and partially removing the phase-changeable layer to expose an upper surface of the preliminary insulation layer pattern.

At least one of the above and other features and advantages of the present invention may be separately realized by providing a phase-changeable memory device, including a substrate including a peripheral region and a cell region, a first pad on the peripheral region, a second pad on the cell region, a lower electrode on the second pad, a multi-layer insulation layer pattern on the substrate, the multi-layer insulation layer pattern including a first opening exposing the lower electrode and a second opening exposing the first pad, a phase-changeable layer pattern including a phase-changeable material and being in the first opening, a metal plug in the second opening, the metal plug having an upper surface higher than that of an upper surface of the multi-layer insulation layer pattern such that the metal plug protrudes above the upper surface of an uppermost layer of the multi-layer insulation layer pattern that directly contacts the metal plug, an upper electrode formed on the phase-changeable layer pattern, and a conductive wiring formed on the metal plug.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a cross-sectional view of an exemplary phase-changeable memory device employing one or more aspects of the present invention; and

FIGS. 2 to 9 illustrate cross-sectional views of stages in an exemplary method of manufacturing the phase-changeable memory device illustrated in FIG. 1.

### DETAILED DESCRIPTION OF THE INVENTION

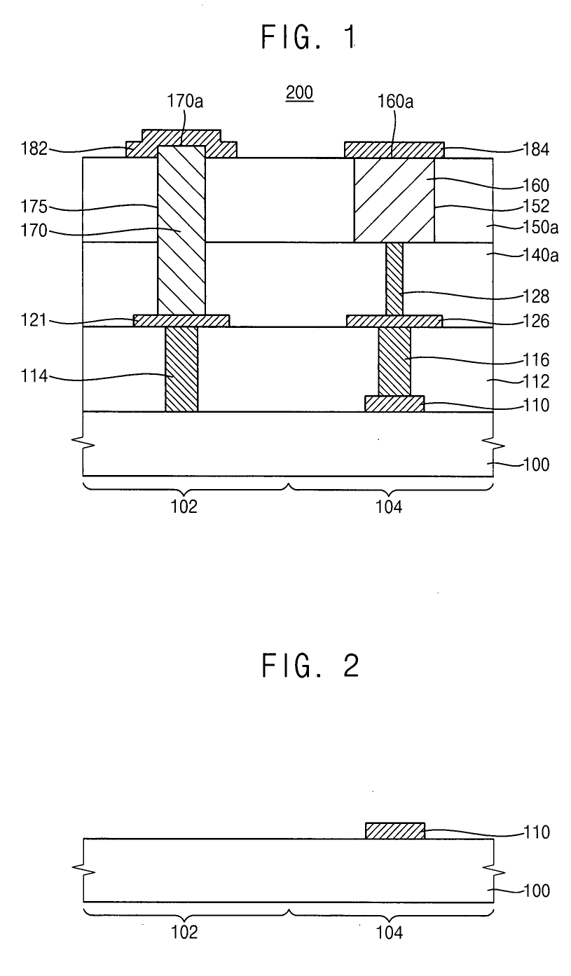

FIG. 1 illustrates a cross-sectional view of an exemplary phase-changeable memory device employing one or more aspects of the present invention.

Referring to FIG. 1, a phase-changeable memory device (PRAM) 200 may include a semiconductor substrate 100, a switching element 110, a first pad 121, a second pad 126, a lower electrode 128, an insulation layer pattern 112, 140a, 150a, a metal plug 170, a phase-changeable layer pattern 160, conductive wiring 182 and an upper electrode 184.

The semiconductor substrate 100 may include a cell region 104 and a peripheral region 102. Cells in which data may be stored may be formed in the cell region 104. Thus, the PRAM 200 including a phase-changeable material may be formed in the cell region 104. The peripheral region 102 may be adjacent to the cell region 104. The switching element 110 may be on the semiconductor substrate 100. The switching element 110 may be adapted to receive an external signal and output the signal. Examples of the switching element 110 may include a diode, a transistor, etc. In the exemplary embodiment described below, a diode is used as the switching element 110, however, embodiments of the invention are not limited thereto.

The first pad 121 may be positioned over the peripheral region 102 of the semiconductor substrate 100. The first pad 121 may be electrically connected to a switching element (not shown) in the peripheral region 102. More particularly, the first pad 121 may be connected to the switching element via a first contact 114. The first pad 121 may include, e.g., a metal such as copper, aluminum, etc. The first pad 121 may, e.g., receive an external signal and may transmit the signal to the PRAM 200 in the cell region 104, or may receive a signal from the PRAM 200 and may transmit the signal to an external element or device (not shown).

The second pad 126 may be arranged over the cell region 104 of the semiconductor substrate 100. The second pad 126 may be electrically connected to the switching element 110 in the cell region 104. More particularly, the second pad 126 may be electrically connected to the switching element 110 via a second contact 116. The second pad 126 may apply a voltage to the PRAM 200. The second pad 126 may have an upper surface that extends along a same or substantially same plane as an upper surface of the first pad 121.

The lower electrode 128 may be on the second pad 126. The lower electrode 128 may be electrically coupled to the second pad 126. The lower electrode 128 may include a conductive material that is capable of generating heat when a current is applied to the lower electrode 128. Examples of the conductive material may include tungsten, titanium, titanium nitride, tantalum, tantalum nitride, molybdenum nitride, niobium nitride, titanium-silicon nitride, aluminum, titanium-aluminum nitride, titanium-boron nitride, zirconium-silicon nitride, tungsten-silicon nitride, tungsten-boron nitride, zirconium-aluminum nitride, molybdenum-silicon nitride, molybdenum-aluminum nitride, tantalum-silicon nitride, tantalum-aluminum nitride, etc. Alternatively, other conductive materials through which a sufficient current flows may be used as the lower electrode 128.

The phase-changeable layer pattern 160 may be on the lower electrode 128. The phase-changeable layer pattern 160 may have an upper surface 160a that extends along a plane closer to the semiconductor substrate 100 than a plane along which an upper surface 170a of the metal plug 170 extends. In some embodiments of the invention, the upper surface 160a of the phase-changeable layer pattern 160 may not extend along a same or substantially same plane as the upper surface 170a of the metal plug 170a. A phase of the phase-changeable layer pattern 160 may be changed to an amorphous structure from a crystalline structure and vice versa in accordance with a size and a shape of a voltage applied to the phase-changeable layer pattern 160. Therefore, a resistance of the phase-changeable layer pattern 160 may be changed in accordance with the phase change, thereby enabling a current passing through the phase-changeable layer pattern 160 to be adjusted.

The phase-changeable layer pattern 160 may include, e.g., chalcogenide. Examples of the chalcogenide may include an element in Group VA-antimony-tellurium such as gernanium-antimony-tellurium (Ge—Sb—Te), arsenic-antimony-tellurium (As—Sb—Te), tin-antimony-tellurium (Sn—Sb—Te), tin-indium-antimony-tellurium (Sn—In—Sb—Te), arsenic-germanium-antimony-tellurium (As—Ge—Sb—Te), silicon-gerrnanium-antimony-tellurium (Si—Ge—Sb—Te), tin-germanium-antimony-tellurium (Sn—Ge—Sb—Te), nitrogen-germanium-antimony-tellurium (N—Ge—Sb—Te), tantalum-antimony-tellurium (Ta—Sb—Te), niobium-antimony-tellurium (Nb—Sb—Te), vanadium-antimony-tellurium (V—Sb—Te), etc., or an element in Group VA-antimony-selenium such as tantalum-antimony-selenium (Ta—Sb—Se) niobium-antimony-selenium (Nb—Sb—Se), vanadium-antimony-selenium (V—Sb—Se), etc. Further, the phase-changeable material may include an element in Group VIA-antimony-tellurium such as tungsten-antimony-tellurium (W—Sb—Te), molybdenum-antimony-tellurium (Mo—Sb—Te), chrome-antimony-tellurium (Cr—Sb—Te), etc., or an element in Group VIA-antimony-selenium such as tungsten-antimony-selenium (W—Sb—Se), molybdenum-antimony-selenium (Mo—Sb—Se), chrome-antimony-selenium (Cr—Sb—Se), etc.

In some embodiments of the invention, each of the unit cells in which one data may be stored may be formed in the cell region 104, however, embodiments of the invention are not limited thereto. In embodiments in which each of the unit cells in which one data may be stored may be in the cell region 104, the phase-changeable layer patterns 160 and the unit cells may have a one-to-one correspondence with each other. Further, each of the unit cells in which one data may be stored may be arranged in series in the cell region 104.

The upper electrode 184 may be on the phase-changeable layer pattern 160. In some embodiments of the invention, the phase-changeable layer pattern 160 may be positioned between the lower electrode 128 and the upper electrode 184. The upper electrode 184 and the lower electrode 128 may apply a voltage to the phase-changeable layer pattern 160. The upper electrode 184 may include a conductive material having, e.g., nitrogen, a metal, a metal silicide, etc.

The metal plug 170 may be on the second pad 121 in the peripheral region 102. The metal plug 170 may be electrically connected to the second pad 121. The metal plug 170 may include, e.g., doped polysilicon, a metal such as tantalum, copper, tungsten, titanium, aluminum, tantalum nitride, copper nitride, tungsten nitride, titanium nitride, aluminum nitride, etc. As discussed above, in some embodiments of the invention, the upper surface 170a of the metal plug 170 may extend along a plane that is further away from the semiconductor substrate 100 than a plane along which the upper surface 160a of the phase-changeable layer pattern 160 extends.

The conductive wiring 182 may be on the metal plug 170. The conductive wiring 182 may have a uniform and/or substantially uniform thickness. In some embodiments of the invention, the conductive wiring 182 may have a stepped structure and may, as shown, e.g., in FIG. 1, surround exposed portion(s) of the conductive plug 170 extending above the third insulation layer pattern 150a. That is, the conductive wiring 182 may cover an upper portion of the metal plug 170. The conductive wiring 182 may be electrically connected to the first pad 121 through the metal plug 170. The conductive wiring 182 may include a conductive material having, e.g., nitrogen, a metal, a metal silicide, etc.

The PRAM 200 may further include the insulation layer pattern 112, 140a, 150a that may electrically insulate the above-mentioned electrical elements in the cell region 104 and the peripheral region 102. In some embodiments of the invention, the insulation layer pattern may have a multi-layered structure such as a double-layered structure or a triple-layered structure. More particularly, e.g., the insulation layer pattern in the exemplary embodiment illustrated in FIG. 1 includes the first insulation layer pattern 112, the second insulation layer pattern 140a and the third insulation layer pattern 150a. However, embodiments of the invention are not limited thereto. For example, in some embodiments of the invention, the insulation layer pattern may include a fourth insulation layer pattern (not shown).

The insulation layer pattern 112, 140a, 150a may be formed on the semiconductor substrate 100. The insulation layer pattern may have a first opening 152 exposing the lower electrode 128 and a second opening 175 exposing the first pad 121.

FIGS. 2 to 9 illustrate cross-sectional views of stages in an exemplary method of manufacturing the phase-changeable memory device illustrated in FIG. 1.

Referring to FIG. 2, the switching element 110 may be formed on the semiconductor substrate 100.

The semiconductor substrate 100 may include the cell region 104 and the peripheral region 102. Cells in which data may be stored may be formed in the cell region 104. Thus, the PRAM 200 including a phase-changeable material may be formed in the cell region 104. The peripheral region 102 may be adjacent to the cell region 104.

The switching element 110 may apply an externally supplied signal to the PRAM. The switching element 110 may include a diode, a transistor, etc. In the exemplary embodiment described herein, the diode is used as the switching element 110. However, embodiments of the invention are not limited thereto. The switching element 110 may be electrically connected to the lower electrode 128 of the PRAM. Therefore, to drive the PRAM 200, an electrical signal may be applied to the PRAM 200 via the switching element 110.

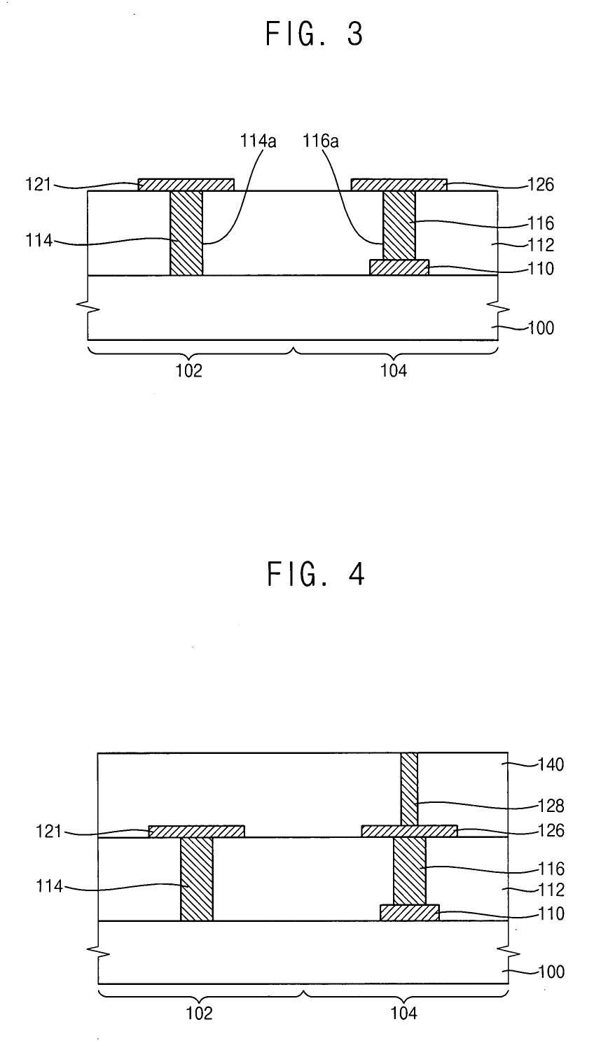

Referring to FIG. 3, a first insulation layer (not shown) may be formed on the semiconductor substrate 100 to cover the switching element 110. The first insulation layer may include, e.g., silicon oxide. The silicon oxide may include, e.g., phosphor silicate glass (PSG), boro-phosphor silicate glass (BPSG), undoped silicate glass (USG), spin-on-glass (SOG), tetra-ethyl-ortho-silicate (TEOS), plasma enhanced TEOS (PE-TEOS), flowable oxide (FOX), high density plasma chemical vapor deposition (HDP-CVD) oxide, etc.

The first pad 121 and the second pad 126 may then be formed on the first insulation layer. First and second contact holes 114a, 116a may be formed through the first insulation layer to form the first insulation layer pattern 112. The first and second contact holes may be filled with the first contact 114 and the second contact 116, respectively. The first contact 114 may be electrically connected to the semiconductor substrate 100 in the peripheral region 102. The second contact 116 may be electrically connected to the switching element 110.

A first conductive layer (not shown) may be formed on the first insulation layer pattern 112. A first photoresist pattern (not shown) may be formed on the first conductive layer. The first conductive layer may be etched using the photoresist pattern as an etching mask to form the first pad 121 and the second pad 126. The first pad 121 may contact the first contact 114, and the second pad 126 may contact the second contact 116. The photoresist pattern may then be removed by an ashing process and/or a stripping process.

The first pad 121 may be arranged in the peripheral region 102 of the semiconductor substrate 100. Further, the second pad 126 may be arranged in the cell region 104 of the semiconductor substrate 100. In some embodiments of the invention, the second pad 126 may be arranged on the second contact 116. Thus, the second pad 126 may be electrically connected to the switching element 110 through the second contact 116.

The first conductive layer may include, e.g., tungsten, aluminum, copper, titanium, tantalum, tantalum nitride, etc. The first conductive layer may be formed by, e.g., a plasma enhanced chemical vapor deposition (PECVD) process, a sputtering process, etc.

Referring to FIG. 4, a second insulation layer (not shown) may be formed on the first pad 121, the second pad 126 and the semiconductor substrate 100. The second insulation layer may include, e.g., silicon oxide. The silicon oxide may include, e.g., phosphor silicate glass (PSG), boro-phosphor silicate glass (BPSG), undoped silicate glass (USG), spin-on-glass (SOG), tetra-ethyl-ortho-silicate (TEOS), plasma enhanced TEOS (PE-TEOS), flowable oxide (FOX), high-density plasma chemical vapor deposition (HDP-CVD) oxide.

An opening may be formed through the second insulation layer to form a preliminary second insulation layer pattern 140. In some embodiments of the invention, a second photoresist pattern (not shown) may be formed on the second insulation layer. The second insulation layer may be etched using the second photoresist pattern as an etching mask to form a preliminary second insulation layer pattern 140 having the opening. The second photoresist pattern may be removed by, e.g., an ashing process and/or a stripping process.

The opening may be filled with the lower electrode 128. The lower electrode 128 may be electrically connected to the second pad 126.

A second conductive layer (not shown) may then be formed on the preliminary second insulation layer pattern 140 and may fill up the opening in the preliminary second insulation layer pattern 140. The second conductive layer may be removed by, e.g., a chemical mechanical polishing (CMP) process until an upper surface of the preliminary second insulation layer pattern 140 is exposed and the lower electrode 128 is formed in the opening.

In some embodiments of the invention, when a margin of the process for forming the opening is insufficient, a spacer may be formed an inner wall of the opening to provide the lower electrode 128 with a diameter smaller than that of the opening.

The lower electrode 128 may include a conductive material that is capable of generating heat when a current is applied to the lower electrode 128. The conductive material may include, e.g., tungsten, titanium, titanium nitride, tantalum nitride, molybdenum nitride, titanium-silicon nitride, titanium-aluminum nitride, titanium-boron nitride, zirconium-silicon nitride, tungsten-silicon nitride, tungsten-boron nitride, zirconium-aluminum nitride, molybdenum-silicon nitride, molybdenum-aluminum nitride, tantalum-silicon nitride, tantalum-aluminum nitride, titanium oxynitride, titanium-aluminum oxynitride, tungsten oxynitride, tantalum oxynitride, etc. These can be used alone or in a combination thereof. In some embodiments of the invention, the lower electrode 128 may include, e.g., polysilicon doped with impurities.

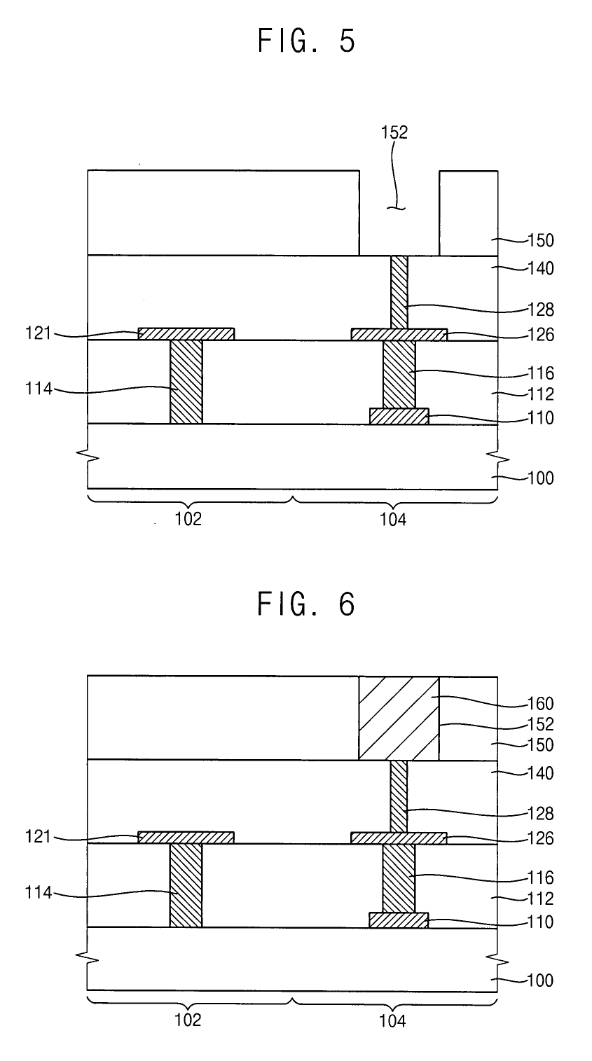

Referring to FIG. 5, a preliminary third insulation layer pattern 150 having a first opening 152 may be formed on the second insulation layer pattern 140 having the lower electrode 128.

In some embodiments of the invention, a third insulation layer (not shown) may be formed on the second insulation layer pattern 140 and the lower electrode 128. The third insulation layer may be formed by, e.g., a CVD process or a PECVD process using silicon oxide. Further, the third insulation layer may have a height corresponding to that of the phase-changeable layer pattern 160 shown in FIG. 1. In some embodiments of the invention, the height of the third insulation layer may be about 200 Å to about 1,000 Å. However, embodiments of the invention are not limited thereto.

A third photoresist pattern (not shown) may be formed on the third insulation layer. The third insulation layer may be etched using the third photoresist pattern as an etching mask to form a preliminary third insulation layer pattern 150 having the first opening 152. The third photoresist pattern may then be removed by, e.g., an ashing process and/or a stripping process. The lower electrode 128 and at least a portion of an upper surface of the preliminary second insulation layer pattern 140 adjacent to the lower electrode 128 may be exposed through the first opening 152. Therefore, a width of the phase-changeable layer pattern 160 shown in FIG. 1 may be wider than that of the lower electrode 128.

For example, in some embodiments of the invention, each of the unit cells in which one data may be stored may be formed in the cell region 104. Further, in some embodiments of the invention, the plurality of the first openings 152 corresponding to the unit cells, respectively, may be formed through the preliminary third insulation layer pattern 150. As a result, in some embodiments of the invention, the phase-changeable layer patterns 160 and the unit cells may have a one-to-one correspondence with each other.

Referring to FIG. 6, a phase-changeable layer (not shown) may be formed on the preliminary third insulation layer pattern 150 and may fill up the first opening 152. The phase-changeable layer may include, e.g., chalcogenide of which a phase may be changed due to heat. Examples of chalcogenide may include an element in Group VA-antimony-tellurium such as germanium-antimony-tellurium (Ge—Sb—Te), arsenic-antimony-tellurium (As—Sb—Te), tin-antimony-tellurium (Sn—Sb—Te), tin-indium-antimony-tellurium (Sn—In—Sb—Te), arsenic-germanium-antimony-tellurium (As—Ge—Sb—Te), silicon-germanium-antimony-tellurium (Si—Ge—Sb—Te), tin-germanium-antimony-tellurium (Sn—Ge—Sb—Te), nitrogen-germanium-antimony-tellurium (N—Ge—Sb—Te), tantalum-antimony-tellurium (Ta—Sb—Te), niobium-antimony-tellurium (Nb—Sb—Te), vanadium-antimony-tellurium (V—Sb—Te), etc., or an element in Group VA-antimony-selenium such as tantalum-antimony-selenium (Ta—Sb—Se) niobium-antimony-selenium (Nb—Sb—Se), vanadium-antimony-selenium (V—Sb—Se), etc. Further, the phase-changeable material may include an element in Group VIA-antimony-tellurium such as tungsten-antimony-tellurium (W—Sb—Te), molybdenum-antimony-tellurium (Mo—Sb—Te), chrome-antimony-tellurium (Cr—Sb—Te), etc., or an element in Group VIA-antimony-selenium such as tungsten-antimony-selenium (W—Sb—Se), molybdenum-antimony-selenium (Mo—Sb—Se), chrome-antimony-selenium (Cr—Sb—Se), etc. In this example embodiment, the germanium-antimony-tellurium (Ge—Sb—Te) is used for the phase-changeable material.

To prevent and/or reduce voids or seams from being formed in the phase-changeable material in the first opening 152, the phase-changeable material may be formed by, e.g., a sputtering process, a CVD process, an atomic layer deposition (ALD) process, etc.

The phase-changeable layer may be planarized until an upper surface of the preliminary third insulation layer pattern 150 is exposed to form the phase-changeable layer pattern 160 in the first opening 152. The phase-changeable layer may be planarized by, e.g., a CMP process.

In some embodiments of the invention, because the phase-changeable layer pattern 160 may be formed in the first opening 152 by the CMP process, the phase-changeable layer pattern 160 may not be damaged due to an etchant used in an etching process. Therefore, electrical characteristics of the phase-changeable layer pattern 160 may still be maintained.

For example, when the first openings 152 correspond to the unit cells in which one data may be stored, respectively, the phase-changeable layer patterns 160 and the unit cells may have a one-to-one correspondence with each other.

A phase of the phase-changeable layer pattern 160 may be changed to an amorphous structure from a crystalline structure and vice versa in accordance with a size and a shape of a voltage applied to the phase-changeable layer pattern 160. Therefore, a resistance of the phase-changeable layer pattern 160 may be changed in accordance with the phase change so that a current passing through the phase-changeable layer pattern 160 may also be changed. As a result, the phase-changeable layer pattern 160 may store data or read data.

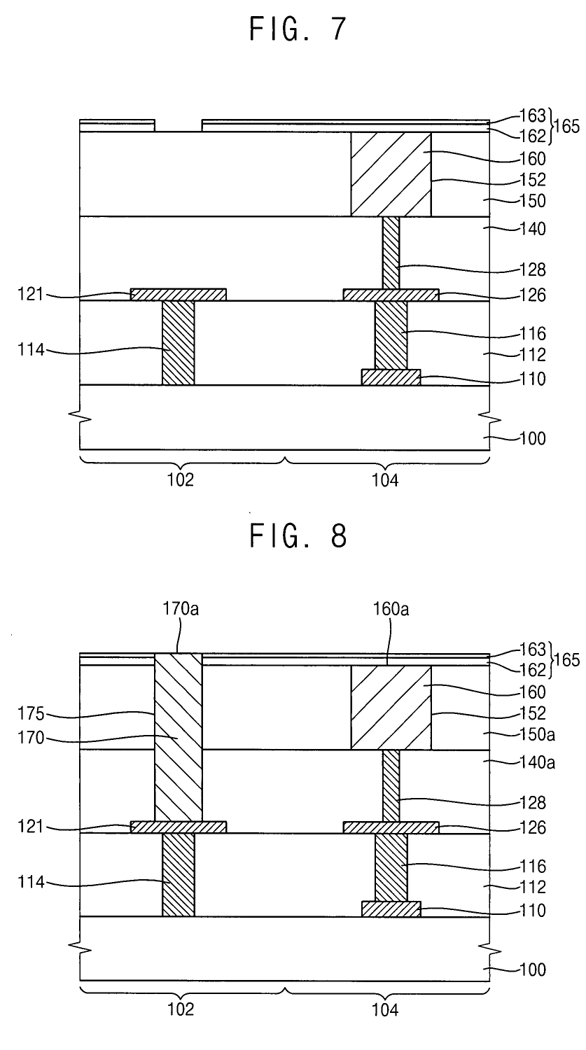

Referring to FIG. 7, a capping layer pattern 165 may be formed on the preliminary third insulation layer pattern 150 and the phase-changeable layer pattern 160.

In some embodiments of the invention, a capping layer (not shown) having a uniform thickness may be formed on the preliminary third insulation layer pattern 150 and the phase-changeable layer pattern 160. The capping layer may have a multi-layered structure. A fourth photoresist pattern (not shown) may be formed on the capping layer. The capping layer may be etched using the fourth photoresist pattern as an etching mask to form the capping layer pattern 165. The capping layer pattern 165 may have an opening for partially exposing the preliminary third insulation layer pattern 150 in the peripheral region 102.

For example, the capping layer pattern 165 may include an oxide layer 162 and a silicon nitride layer 163 formed on the oxide layer 162. In some embodiments of the invention, the capping layer pattern 165 may include a metal layer (not shown) and a silicon nitride layer formed on the metal layer. The silicon nitride layer 163 of the capping layer pattern 165 may serve as an etching stop layer in a CMP process for forming a metal plug.

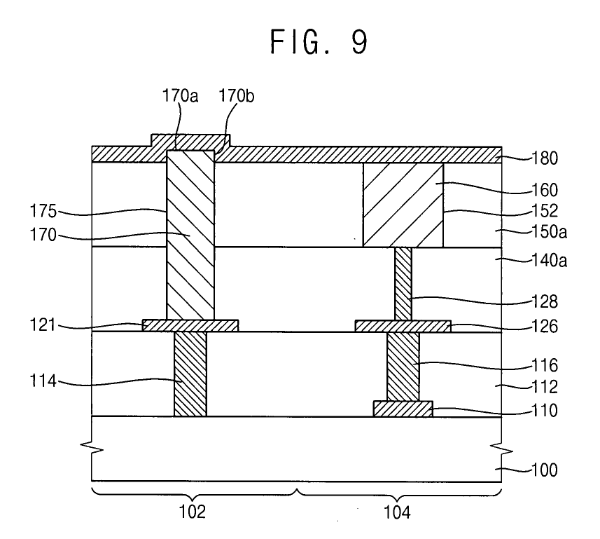

Referring to FIG. 8, the second opening 175 may be formed through the preliminary third insulation layer pattern 150 and the preliminary second insulation layer pattern 140.

In some embodiments of the invention, the preliminary third insulation layer pattern 150 and the preliminary second insulation layer pattern 140 may be sequentially etched using the capping layer pattern 165 to form the third insulation layer pattern 150a and the second insulation layer pattern 140a that have the second opening 175 exposing the first pad 121.

A metal layer (not shown) may be formed on the capping layer pattern 165 and may fill up the second opening 175. The metal layer may include, e.g., a metal such as copper, tantalum, tungsten, titanium, aluminum, etc. The metal layer may be formed by a CVD process, a sputtering process, a physical vapor deposition (PVD) process, etc.

The metal layer may be removed until an upper surface of the capping layer pattern 165 is exposed to form the metal plug 170 in the second opening 175. In some embodiments of the invention, the upper surface 170a of the metal plug 170 may protrude above an upper surface of the third insulation layer pattern 150a. The metal plug 170 may be electrically connected to the first pad 121.

During formation of the second opening 175 and the metal plug 170, the capping layer pattern 165 may protect the phase-changeable layer pattern 160 including the phase-changeable material. Thus, the phase-changeable layer pattern 160 may not be physically and/or chemically damaged during the etching process for forming the second opening 175.

Referring to FIG. 9, a fourth conductive layer 180 may be formed on the third insulation layer pattern 150a, the metal plug 170 and the phase-changeable layer pattern 160.

Further, as shown in FIG. 9, the capping layer pattern 165 on the third insulation layer pattern 150a may be removed after forming the metal plug 170 and before forming the fourth conductive layer 180. In some embodiments of the invention, the capping layer pattern 165 may have a multi-layered structure, and in such embodiments, e.g., the layers in the capping layer pattern 165 may be sequentially removed.

In some embodiments of the invention, the metal plug 170 may protrude upward from the third insulation layer pattern 150a by a thickness of the capping layer pattern 165.

In some embodiments of the invention, the fourth conductive layer 180 may have a uniform and/or substantially uniform thickness. The fourth conductive layer 180 may be electrically connected to the phase-changeable layer pattern 160 and the metal plug 170. In some embodiments of the invention, the fourth conductive layer 180 may contact the upper surface 170a and side surface(s) 170b of the protruded portion of the metal plug 170.

Examples of a conductive material in the fourth conductive layer 180 may include tungsten, titanium, titanium nitride, tantalum, tantalum nitride, molybdenum nitride, niobium nitride, titanium-silicon nitride, aluminum, titanium-aluminum nitride, titanium-boron nitride, zirconium-silicon nitride, tungsten-silicon nitride, tungsten-boron nitride, zirconium-aluminum nitride, molybdenum-silicon nitride, molybdenum-aluminum nitride, tantalum-silicon nitride, tantalum-aluminum nitride, etc. These can be used alone or in a combination thereof.

In some embodiments of the invention, after removing the capping layer pattern 165, an additional CMP process may not be carried on the fourth conductive layer 180. Therefore, a cost and a yield of the PRAM may be improved.

Referring again to FIG. 1, the fourth conductive layer 180 may be patterned to form the conductive wiring 182 and the upper electrode 184. In some embodiments of the invention, the conductive wiring and the upper electrode may be simultaneously and/or substantially simultaneously formed.

Particularly, an etching mask may be formed on the fourth conductive layer 180. The fourth conductive layer 180 may be etched using the etching mask to form the conductive wiring 182 and the upper electrode 184. The conductive wiring 182 may be placed on the metal plug 170. The upper electrode 182 may be positioned on the phase-changeable layer pattern 160.

In embodiments of the invention, the capping layer pattern through which the insulation layer in the peripheral region may be partially exposed may be formed on the insulation layer having the phase-changeable layer pattern. The insulation layer may be patterned using the capping layer pattern to form the opening through the insulation layer. Therefore, the capping layer pattern may protect the phase-changeable layer pattern during the etching process for forming the opening through the insulation layer and thus, the phase-changeable layer pattern may not be damaged.

Further, after the metal plug is electrically connected to the first pad, additional processes may be performed without performing an additional CMP process so that a process for forming the PRAM may be simplified.

The present invention is described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s), as may be illustrated in the accompanying figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A phase-changeable memory device, comprising:
a substrate including a peripheral region and a cell region;
a first pad on the peripheral region;
a second pad on the cell region;
a lower electrode on the second pad;
an insulation layer pattern on the substrate, the insulation layer pattern including a first opening exposing the lower electrode and a second opening exposing the first pad;
a phase-changeable layer pattern including a phase-changeable material and being in the first opening;
a metal plug in the second opening, the metal plug having an upper surface higher than that of an upper surface of the phase-changeable layer pattern;
an upper electrode formed on the phase-changeable layer pattern; and
a conductive wiring formed on the metal plug.

2. The phase-changeable memory device as claimed in claim 1, wherein the first and second pads have upper surfaces extending along substantially a same plane.

3. The phase-changeable memory device as claimed in claim 1, further comprising a switching element electrically connected to the lower electrode.

4. The phase-changeable memory device as claimed in claim 1, wherein the lower electrode and the phase-changeable layer pattern have a one-to-one correspondence with each other.

5. The phase-changeable memory device as claimed in claim 1, wherein the metal plug protrudes upward from an upper surface of the insulation layer pattern.

6. The phase-changeable memory device as claimed in claim 1, wherein the insulation layer pattern is a multi-layer structure.

7. The phase-changeable memory device as claimed in claim 1, wherein an upper surface of the phase-changeable layer pattern extends on substantially a same plane as a plane along which an upper surface of the insulation layer pattern extends.

8. The phase-changeable memory device as claimed in claim 7, wherein the conductive wiring contacts a portion of the upper surface of the insulation layer pattern that extends along substantially the same plane as the plane along which the upper surface of the phase-changeable layer pattern extends.

9. The phase-changeable memory device as claimed in claim 1, wherein the conductive wiring contacts an upper surface and at least one side surface of an upper portion of the metal plug.

10. The phase-changeable memory device as claimed in claim 1, wherein the conductive wiring has a stepped structure having a substantially uniform thickness.

11. A method of manufacturing a phase-changeable memory device, comprising:
forming an insulation layer on a substrate including a peripheral region on which a first pad is formed and a cell region on which a second pad and a lower electrode are sequentially formed;
patterning the insulation layer to form a preliminary insulation layer pattern having a first opening exposing the lower electrode;
filling the first opening with a phase-changeable layer pattern;
patterning the preliminary insulation layer pattern on the peripheral region to form an insulation layer pattern having a second opening exposing the first pad;
filling the second opening with a metal plug that has a protruded portion that protrudes from the insulation layer pattern; and
forming conductive wiring and an upper electrode on the insulation layer pattern, the conductive wiring being electrically connected to the metal plug and the upper electrode being electrically connected to the phase-changeable layer pattern.

12. The method as claimed in claim 11, wherein forming the insulation layer pattern comprises:
forming a capping layer pattern on the preliminary insulation layer pattern, the capping layer pattern partially exposing the preliminary insulation layer pattern in the peripheral region; and
etching the preliminary insulation layer pattern using the capping layer pattern as an etching mask to form the insulation layer pattern.

13. The method as claimed in claim 12, wherein the capping layer pattern comprises an oxide/silicon nitride layer or a metal/silicon nitride layer.

14. The method as claimed in claim 12, wherein forming the metal plug comprises:
forming a metal layer on the capping layer pattern to fill up the second opening;
partially removing the metal layer to expose an upper surface of the capping layer pattern; and
removing the capping layer pattern.

15. The method as claimed in claim 11, wherein the conductive wiring and the upper electrode are simultaneously formed.

16. The method as claimed in claim 11, wherein forming the conductive wiring and the upper electrode, comprises:
forming a conductive layer having a uniform thickness on the phase-changeable layer pattern and the metal plug; and
patterning the conductive layer to form the conductive wiring on the metal plug and the upper electrode on the phase-changeable layer pattern.

17. The method as claimed in claim 16, wherein the conductive layer comprises tungsten, titanium, titanium nitride, tantalum, tantalum nitride, molybdenum nitride, niobium nitride, titanium-silicon nitride, aluminum, titanium-aluminum nitride, titanium-boron nitride, zirconium-silicon nitride, tungsten-silicon nitride, tungsten-boron nitride, zirconium-aluminum nitride, molybdenum-silicon nitride, molybdenum-aluminum nitride, tantalum-silicon nitride, tantalum-aluminum nitride or a combination thereof.

18. The method as claimed in claim 11, wherein the phase-changeable layer pattern comprises germanium-antimony-tellurium (Ge—Sb—Te), arsenic-antimony-tellurium (As—Sb—Te), tin-antimony-tellurium (Sn—Sb—Te), tin-indium-antimony-tellurium (Sn—In—Sb—Te), arsenic-germanium-antimony-tellurium (As—Ge—Sb—Te) or indium-antimony-tellurium-silver (In—Sb—Te—Ag).

19. The method as claimed in claim 11, wherein forming the phase-changeable layer pattern comprises:
forming a phase-changeable layer on the preliminary insulation layer pattern to fill up the first opening; and
partially removing the phase-changeable layer to expose an upper surface of the preliminary insulation layer pattern.

20. A phase-changeable memory device, comprising:
a substrate including a peripheral region and a cell region;
a first pad on the peripheral region;
a second pad on the cell region;
a lower electrode on the second pad;
a multi-layer insulation layer pattern on the substrate, the multi-layer insulation layer pattern including a first opening exposing the lower electrode and a second opening exposing the first pad;
a phase-changeable layer pattern including a phase-changeable material and being in the first opening;
a metal plug in the second opening, the metal plug having an upper surface higher than that of an upper surface of the multi-layer insulation layer pattern such that the metal plug protrudes above the upper surface of an uppermost layer of the multi-layer insulation layer pattern that directly contacts the metal plug;
an upper electrode formed on the phase-changeable layer pattern; and
a conductive wiring formed on the metal plug.
